(19) United States
(12) Patent Application Publication
(10) Pub. No.: US 2021/0057311 A1
(43) Pub. Date: Feb. 25, 2021

(54) METHOD AND SYSTEM OF STRETCHING AN ACCEPTOR SUBSTRATE TO ADJUST PLACEMENT OF A COMPONENT

(71) Applicant: SelfArray, Inc., Troy, NY (US)

(72) Inventors: Clinton Ballinger, Burnt Hills, NY (US); Michael Conward, Troy, NY (US); Pei-I Wang, Clifton Park, NY (US)

(21) Appl. No.: 16/998,400

(22) Filed: Aug. 20, 2020

Related U.S. Application Data
(60) Provisional application No. 62/890,715, filed on Aug. 23, 2019.

(51) Int. Cl. H01L 23/498; H01L 23/00

(52) U.S. Cl. CPC H01L 23/4985; H01L 24/95

(57) ABSTRACT

Disclosed herein is a system and method of adjusting a location of components on a receiving substrate. The method includes transferring a set of components from a donor substrate to a receiving substrate and stretching the receiving substrate in at least one direction so the components are in their final location. The system includes a set of components on a receiving substrate; and wherein the receiving substrate is configured to adjust the location of the set of components via elastic stretching in at least one direction.

### FIELD OF THE INVENTION

The present invention relates to methods and systems for transferring components from a donor to an acceptor substrate and subsequently adjusting the location on the acceptor substrate to reach the final configuration.

### BACKGROUND

Modern electronic components continue to get smaller and hence can be difficult to handle using traditional assembly technologies that were designed for larger sized components. The advent of micro and mini-LEDs has pushed the limits of assembly technology and many researchers are looking for ways to assemble vast numbers of tiny electronic components quickly and accurately. Methods like pick-and-place, where a component is “picked” from the native substrate wafer or other interposer substrate and then “placed” into the final location on the circuit board or other substrate, have historically been used for manufacturing. However, these methods are ill-suited for some applications especially as components get smaller.

Companies like Motorola have developed methods (U.S. Pat. No. 5,941,674) where a donor substrate is moved to a pick-up position, where an ejector pin is moved upwards through a compartment, such that the component is lifted from the carrier. Simultaneously, a pick-up element is moved towards the component from a side of the carrier remote from the pin, such that the component is picked up by said element by means of vacuum. The component is then moved to a desired position on a substrate by the pick-up element. This method allows for smaller components to be picked and placed but there are still restrictive size limits on this methodology.

As components have gotten smaller, pick and place becomes less efficient and often cannot be used because the components are too small. In addition, pick and place is inherently serial and, if millions of components need to be assembled, then millions of pick and place steps are needed, causing the method to be slow.

Methods like laser induced forward transfer (LIFT) use a laser to induce a transfer from a donor substrate to an acceptor substrate. Since a laser is used, the method can be faster than pick and place. However, final alignment of the components on the acceptor substrate requires the donor, the acceptor or both to move and find their position with great accuracy. In addition, the LIFT method relies on the component being forced off the donor substrate with a laser pulse, which often results in positional location accuracy issues on the acceptor substrate.

Early work on laser forward transfer methods was performed over 20 years ago by Holmes et al. (Holmes et al, J. Microelectromech. Syst., 7, (1998) 416, and Pique et al. (Proc. SPIE 6606, Advanced Laser Technologies 2006, 66060R (25 Apr. 2007). Holmes et al developed laser-transfer processes for assembly of micro electro-mechanical structures. Other researchers have developed methods for LIFT for small LEDs that can be bonded via flip chip bonding or transferred with patterned or active side facing up, enabling direct-write approaches to print the electrical interconnects.

Inventors such as Weekamp—US2006/0081572 A1 and 8,661,655B, teach of a moving “carrier” to a location above the final location then release of component by shining a light. This forms the basis of many LIFT techniques but again is limited because of positional accuracy and speed issues when moving substrates to a final accurate position before transferring the component.

For most transfer methods, the components are first removed from their native substrate and reconstructed on another substrate. In this case, the native substrate refers to the surface upon which the components were grown and processed. For example, LEDs are grown on a wafer then singulated via dicing to produce individual LEDs, however they are typically still contiguous on a substrate until transferred. Transfer steps from substrate to substrate typically result in locational uncertainty so keeping components on their native substrate would be ideal. Since the components are tightly packed together pick and place and LIFT techniques do not perform well, hence the need for transfer to another substrate.

### BRIEF SUMMARY

Disclosed herein are methods and materials, which can be used for the final configuration of components once they are released from a donor substrate to a provisional location of an acceptor substrate. This becomes particularly important in transferring electronic components from donor to receiver substrates in micro-scale transfer or positioning applications. Researchers are still trying to develop transfer systems that improve positioning for micro and mini sized electronic components. Often these transfer mechanisms have to be very reliable and very accurate, e.g., between 1-10 μm of the final location upon transfer to the acceptor substrate for mini/micro LEDs. Current methodologies and materials fall short of the accuracy and transfer efficiency goals for the electronics industry.

The shortcomings of the prior art are overcome and additional advantages are provided through the provisions, in one aspect, a method. The method comprises transferring a plurality of components from a donor substrate to a receiving substrate. The method further comprises elastically stretching the receiving substrate in at least one direction so the components are in a larger surface area defined by a predetermined spacing or pitch for a device.

Another aspect of the present invention includes a system, in one aspect, that includes: a receiving substrate, the receiving substrate having an elasticity; a plurality of components being affixed to the receiving substrate, the plurality of components being a distance apart defined by a distance of the plurality of components when formed; and a substrate stretcher that stretches the receiving substrate such that a location of the set of components is adjusted by a force applied to the receiving substrate via the substrate stretcher stretching in at least one direction.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment where 100 represents transfer material, 200 are the singulated components that also have a “transfer layer” on top.

FIG. 2 shows 100 which is the transfer material, diced components from the wafer directly 200, and 400 which is a stretchable stamp with pillars 410 arranged to pick up from the diced wafer pitch.

FIG. 3 depicts the stretchable stamp, 400, with pillars in relaxed position and 400′ which is the stretched position to fit the final pitch specifications.

FIG. 4 shows 100 which is the transfer material, diced components from the wafer directly 200, and 400 which is a stretchable stamp used to pick up from the diced wafer pitch.

FIG. 5 depicts the stretchable stamp in unstretched position 400 and 400′ which is the stretched position to fit the final pitch specifications. Electronic components are shown as 500 as transferred to the elastomer stamp and 500′ represents the location in the stretch position.

FIG. 6 shows 100 which is the transfer material, diced components from the wafer directly 200, and 400 is the acceptor substrate with 410.

FIG. 7 shows 100 which is the transfer material, diced components from the wafer directly 200, and 400 is the acceptor substrate with 410.

### DETAILED DESCRIPTION

Illustrative embodiments will now be described more fully herein with reference to the accompanying drawings, in which illustrative embodiments are shown. It will be appreciated that this disclosure may be embodied in many different forms and should not be construed as limited to the illustrative embodiments set forth herein. Rather, these embodiments are provided so that this disclosure will be thorough and complete and will fully convey the scope of this disclosure to those skilled in the art.

Furthermore, the terminology used herein is for the purpose of describing particular embodiments only and is not intended to be limiting of this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. Furthermore, similar elements in different figures may be assigned similar element numbers. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Unless specifically stated otherwise, it may be appreciated that terms such as “processing”, “detecting”, “determining”, “evaluating”, “receiving”, or the like, refer to the action and/or processes of a computer or computing system, or similar electronic data center device, that manipulates and/or transforms data represented as physical quantities (e.g., electronic) within the computing system's registers and/or memories into other data similarly represented as physical quantities within the computing system's memories, registers or other such information storage, transmission, or viewing devices. The embodiments are not limited in this context.

The shortcomings of the prior art are overcome and additional advantages are provided through the present invention including, for instance: releasing the component from the native substrate to a location that is close to the final desired location and using levitation, magnetic attraction, shape memory materials, elastic stretching, and/or the like to move the component to the final location.

Also disclosed is a system, in one aspect, that includes: a donor substrate with components that are affixed via adhesion force, releasing of one or more components to be transferred, transferring them to an acceptor substrate, and then adjusting the location to fit the desired specifications.

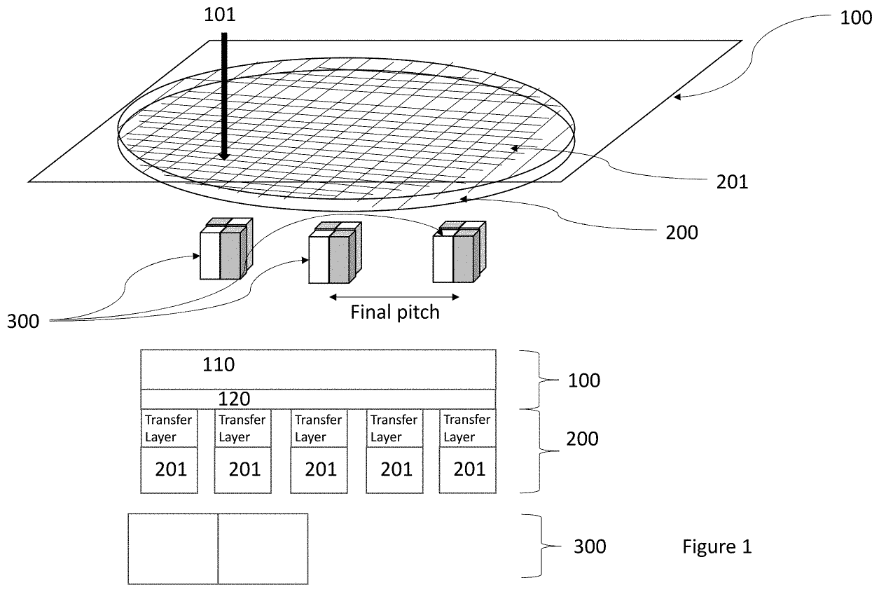

Turning to FIG. 1, a transfer material 100 is provided on a wafer 200. The wafer 200 can include any diced wafer comprising singulated components 201. Singulated components 201 can be any electronic device that is now known or later developed to be formed en mass on wafer 200 and separated from other components on wafer 200 via a dicing procedure. In an embodiment, singulated components 201 are LEDs, although other embodiments are envisioned. In any case, these components may have been singulated by any now known or later developed dicing technique to isolate each component 201. In some embodiments, a laser has rastered across wafer 200 and stress has been applied to wafer 200 (e.g., by stretching slightly, bending, and/or the like) to facilitate separation (e.g., cracks) between components 201.

Transfer material 100 can include any donor substrate capable of releasing components upon application of heat, energy or force of any kind before transferal of the component to the next substrate. For instance, transfer material 100 may include a transfer substrate with an adhesive for holding wafer 200, and thus singulated components 201, in their original formation until released from the transfer material 100. Transfer material 100 allows for movement of wafer 200 to an area where the release will take place, for instance to the vicinity of a bin for collecting components 201. In some embodiments, the components 201 of wafer 200 can be provided configured to be released from transfer material 100 through the application of heat, as disclosed in co-pending application number (BALL-0003 Serial No.), the contents of which are hereby incorporated herein by reference. In one embodiment, as illustrated in FIG. 1, energy is applied to or in the vicinity of the transfer material 100 in the direction of the arrow 101. Energy can include heat, light, laser radiation, conduction, etc. The thermal energy can be applied through transfer material 100, which may include a thermal release material, to diced wafer 200 with singulated components 201. Upon application of energy, components 201 are released from the transfer material 100. The applied energy reduces the attraction force of transfer material 100 such that gravity, or an applied force, removes components 201 from the transfer material 100. In other embodiments, transfer material 100 can include any adhesive layer which releases components after application of a physical force to wafer 200. This physical force can include, but is not limited to, heat, vibration, pressure, vacuum, Van der Waals forces, adhesive forces, electrostatic forces, chemical reduction of adhesive strength and/or other physical forces that are now known or later discovered.

Still referring to FIG. 1, a set of magnetic stages 300 with a desired pitch, such as the illustrated two by two stage, are positioned in the desired pitch, or distance apart, causing self-assembly of the components. For instance, a desired pitch can be determined based on the desired final product utilizing components 201, with magnetic stages 300 separated from one another at a distance based upon this desired pitch of the components 201. In another example related to LEDs, the pitch can be defined by the final desired separation between LEDs that are acting as pixels in a display and hence the pitch defines the pixel density of the display. Pixel density can be defined as a measure of the number of pixels per square area of display. For example, the pixel density of a large outdoor display might be a few pixels per square inch while 100's of pixels per square inch are typical for phone displays. In any case, magnetic stage 300 can be positioned near wafer 100 to apply a stronger attraction force to components 201 than transfer material 100 once released. Components 201 may include a diamagnetic portion of the component for guiding components 201 to the magnetic stages 300. For instance, each component may have a layer of diamagnetic material, including but not limited to pyrolytic graphite. As such, when heat or other energy is applied in direction 101 to transfer material 100, components 201, including a magnetic material, are released. When components 201 are released, the magnetic stage 300 applies a stronger attraction force on components 201 than the transfer material 100, causing components 201 to travel toward and to magnetic stage 300. By virtue of the alignment and pitch of magnetic stage 300, components 201 are arranged according to the desired pitch.

Diamagnetic self-assembly onto a stage gives control of a drop zone as defined by the magnetic lifting force profile of magnetic stage 300 relative to components 201, such that the component is moved into the final location. A drop zone of a size of approximately the magnet dimension, which may be three times the component dimension, but can be smaller or larger, depending on the forces utilized. The diamagnetic component of the LED or other component will guide the component to a portion of the magnetic stage 300 for proper placement.

As illustrated in FIG. 1, the transfer material 100 can include, for instance, a backing layer and adhesive layer. Wafer 200 can include a transfer layer, typically the native substrate, and a plurality of components connected therewith.

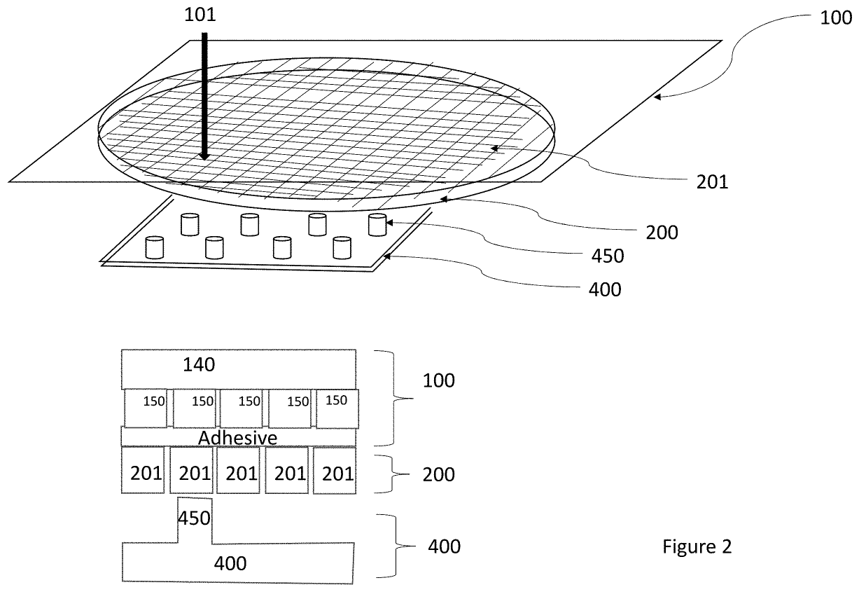

Turning to FIGS. 2-5, in another embodiment, rather than magnetic stage, a stamp 400 may be provided, comprising a receiving substrate. Stamp 400 can include any material with elastic stretching capability, including but not limited to elastic materials, viscoelastic materials, elastomers, and shape memory materials with or without additives such as magnetic particles, for instance quartz fiber, phosphor bronze, rubbers, and PDMS, In some embodiments, stamp 400 can include a material with stretching capabilities that allow the stamp to stretch to its elastic limit, which could be a few percentage points (e.g., 5 to 20%) larger than its original size or, in a highly elastic material, could be multiple times (e.g., 2 to 5 times) its original size. It should also be understood that in some embodiments, stamp 400 may be stretched right to the point of or beyond its elastic strain limit. In such cases, upon relaxation, the material would generally not return to its exact pre-stretched shape, but return to a, potentially non-linear shape that is close enough to the original shape to perform the necessary component transfer. In some embodiments the stamp 400 may be stretched to a point well below the elastic limit of the material and return to its original size.

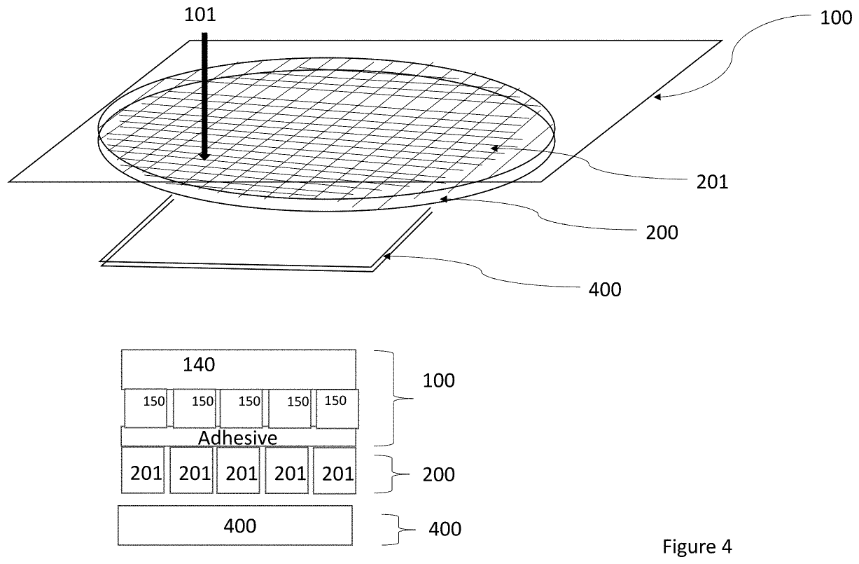

In any case, as illustrated in FIG. 2, stamp 400 may include pillars 450 for accepting components of wafer 200. Pillars 450 include raised areas of stamp 400 or a size similar to components 201 for accepting components 201 after release. Pillars 450 may be comprised of native stamp material and/or include additives to adjust adhesion properties such as spray adhesives, incorporated adhesives, surface layer modification to change adhesion, and applied adhesive layers. Alternatively, as illustrated in FIG. 4, no pillars are present, and components are transferred directly to stamp 400. As shown, transfer material 100 can include more than one layer, for instance a backing layer 140 and a transfer layer 150. This transfer material 100 can be of the same material as described in reference to transfer material of FIG. 1, or may include other releasable adhesive materials.

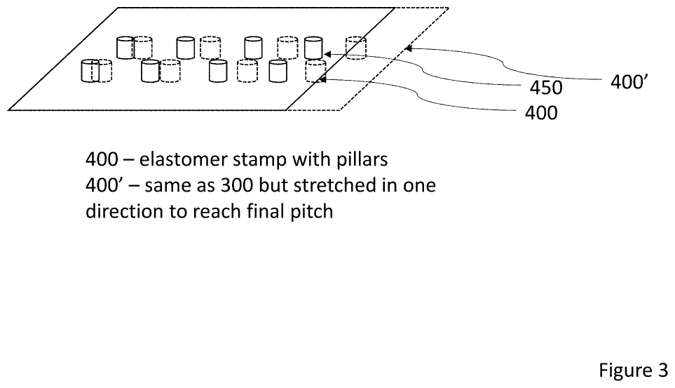

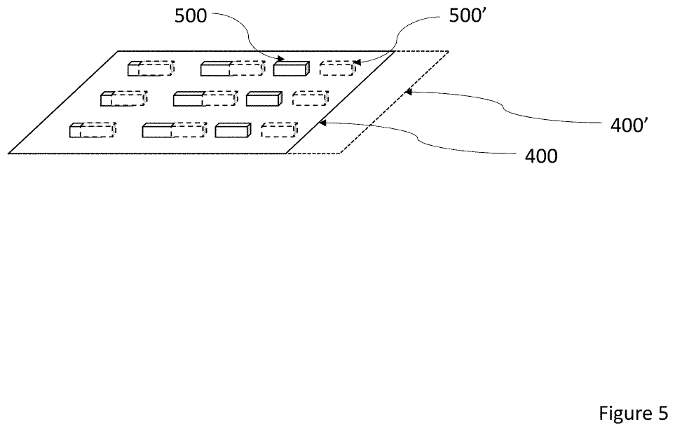

Turning to FIGS. 3 and 5, after the components have been transferred to stamp 400, with or without pillars 450, stamp 400 can be stretched in one or more directions allowing for the transferred components to be arranged into a final desired pitch, or location. In an embodiment, stretching can include applying a transverse force in order to increase a surface area (e.g., a planar area) of the stamp 400 in one or more directions. Components 201 are affixed to stamp 400 in their original location. Upon application of the transverse force, the increased distance rearranges components 201 relative to their original location. By applying a force determined by the distance necessary to rearrange components 201, a new pitch is defined through application of this force. FIG. 3 illustrates stretching of stamp 400 including pillars 450, upon which components 201 are affixed, and FIG. 5 illustrates stretching of stamp 400 with no pillars, wherein components 201 are affixed in their original location. As illustrated, stamp 400 may be stretched in one direction to move the location of components 500 in their original transferred location to be spread out and moved to desired location 400′. Although shown stretched in a single direction, it should be understood that stamp may be stretched in a plurality of directions in order to control the relative location of components 500 in more than one dimension. Additionally, while stretching in two directions could be used to control the dimensions in an effective x and y direction, a singular force applied in a diagonal direction relative to a corner of stamp 400 could also provide the same benefit, effectively stretching simultaneously in an x and y plane. In some embodiments, radial stretching or hoop stretching may be used, wherein stamp 400 is stretched radially about an axis in all directions simultaneously.

It should be understood that the hoop stretching described herein is not to be confused with the use of hoop stretching to perform the initial separation of components in a stealth diced wafer. In contrast, the teachings of this disclosure differ in that, inter alia, the entire wafer is not hoop stretched, but rather, the selected components are stretched after they have already been transferred to the stamp. This means there is more space between the components compared to a stealth diced wafer and a more accurate and precise final placement of the components on the stamp can be achieved as a result of this elastic stretching. For example, stealth diced components may be 20 μm apart from each other so if they are stretched to 40 μm apart, that represents 100% strain which, in most cases, is no longer in the linear elastic regime, leading to uncertainties. In this invention, the components being stretched are typically spaced 100's of μm apart. As such, a 20 μm stretch results in much lower strain to the stamp 400. Accordingly, the change in pitch of components 201 using stamp 400 allows for an elastic stretching which is linear. The change in pitch is thus more accurate than previous methods of changing pitch and is reproducible for future applications. Linearity of the stretched components is achieved utilizing the disclosed methods.

In an alternative embodiment to the illustration of FIGS. 3 and 5, a stamp with or without pillars may be provided that has previously been elastically stretched. Once the components are transferred, the stamp may be relaxed in one or more directions allowing for the transferred components to be arranged into a final desired pitch, or location, as well. While this embodiment is not illustrated, it should be understood to one of skill in the art.

With reference to the stretching of stamp 400, unlike plasticity where permanent deformation occurs, the materials comprising the stamp have an elastic deformation regime that defines their ability to return to their original shape post stretching. The well-known Hooke's Law describes this process via a linear equation describing the strain of a material. Hence for relatively small strains (material-dependent) linear expansion is observed when a force is applied. This fact is used in the present invention in order to move the component from the provisional location 400 (which is regularly spaced, just not at the desired final pitch) to the final location 400′. In some embodiments, stamp 400 may return to approximately the original shape when the force applied for stretching is removed.

Some materials that may be used for stamp 400 combine plasticity and elastic deformation. In some embodiments shape memory polymers may be utilized. For instance, shape memory polymers may include a material which, when stretched, can retain the new size and form. Therefore, when the force applied to stretch stamp 400 is removed, the shape memory material retains the stretched configuration and thus the components 201 are in their desired final location. Said material may be returned to an original size and shape, for instance through thermal activation, which would allow it to be used for another transfer. This retention of shape would allow for minor changes and alterations without having to apply the original force of deformation. It should be understood that thermal activation can include the application of heat and/or cold in order to initiate expansion of stamp 400 or shrinkage of stamp 400.

While described with reference to a flat stamp 400, it should be understood that the features of the present invention could be applied to roll-to-roll type processing, and stretching of rolled material for the transfer as well.

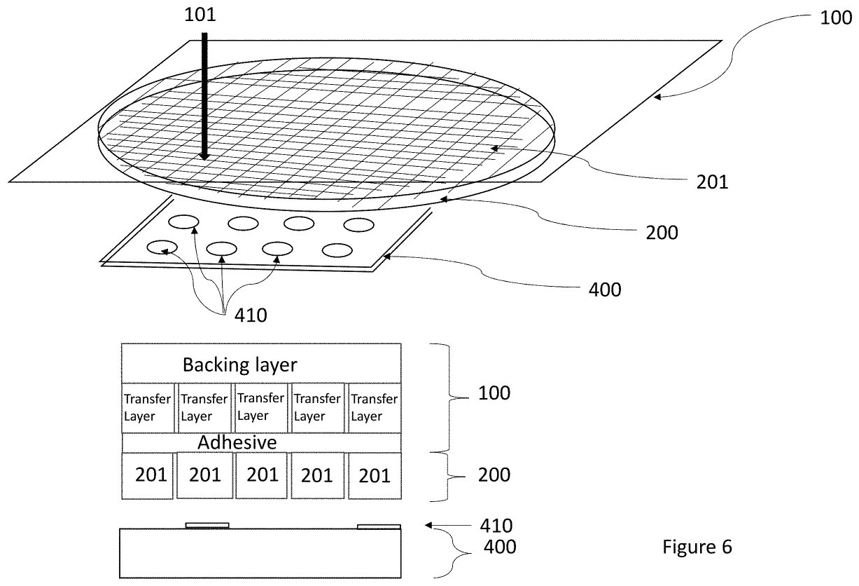

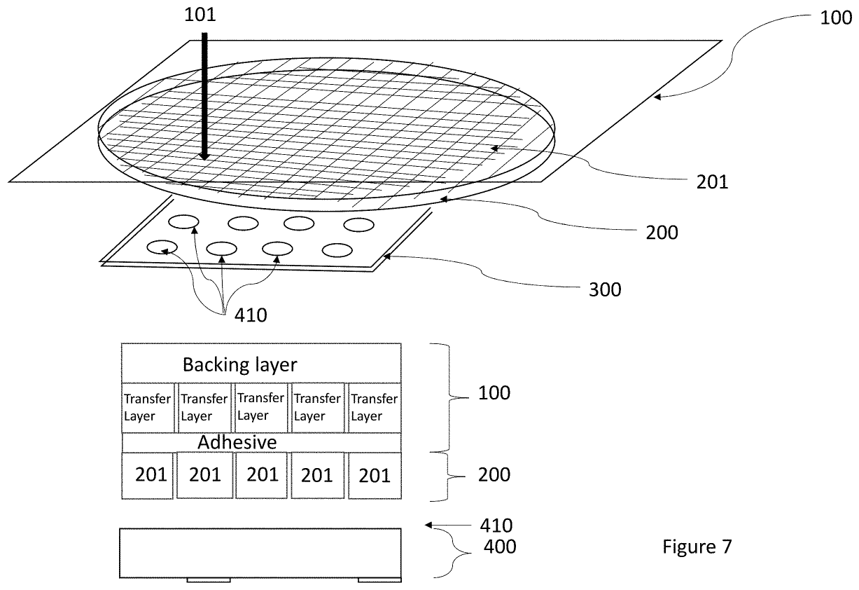

In yet another embodiment, as illustrated in FIGS. 6 and 7, an acceptor substrate 300 can be provided below the substrate 200, including a set of magnetic regions 310 above the acceptor substrate (FIG. 6) or below the acceptor substrate (FIG. 7), allowing for approximate locations of components to be more accurate by utilizing the magnetic regions 410 to guide the components to a desired location. These regions may be permanent or movable as well. That is, acceptor substrate 400 may be stretchable as above, or the substrate may simply allow for the magnetic regions 410 to guide the placement of components to a desired architecture.

As will be understood to one of skill in the art, the disclosed methods allow for more accurate placement of components on an acceptor substrate, without requiring a final position, as the position can be altered by the disclosed methods to meet final spacing needs. This allows for a more dynamic approach to transferring of components. In some embodiments, the receiving substrate, or stamp 400, is stretched to a final pitch, arranging the components 201 in a predetermined arrangement. However, the receiving substrate may not be a final substrate, and components 201 may still be applied to a final substrate or device, placing them in the desired pitch for a final substrate or device.

It is apparent that there has been provided herein approaches for positioning micro-components on a receiving substrate. While the invention has been particularly shown and described in conjunction with exemplary embodiments, it will be appreciated that variations and modifications will occur to those skilled in the art. Therefore, it is to be understood that the appended claims are intended to cover all such modifications and changes that fall within the true spirit of the invention.

1. A method, the method comprising:
transferring a plurality of components from a donor substrate to a receiving substrate; and
stretching the receiving substrate in at least one direction so the components are in a larger surface area where all components are separated by a new predetermined spacing.

2. The method of claim 1, wherein the stretching includes at least one of: elastic or plastic deformation.

3. The method of claim 1, wherein the receiving substrate has a set of pillars, wherein the components are transferred to the set of pillars, and wherein the stretching increases a planar distance between the set of pillars to a predetermined pitch, positioning the plurality of components to the new predetermined spacing, wherein the new predetermined spacing is substantially uniform.

4. The method of claim 1, wherein the receiving substrate comprises at least one of: elastic materials, viscoelastic materials, elastomers, and shape memory materials including polymers.

5. The method of claim 1, wherein the receiving substrate is elastically stretched in at least two directions.

6. The method of claim 1, wherein the receiving substrate returns to an original shape after stretching.

7. The method of claim 1, wherein the receiving substrate maintains a stretched shape after being elastically stretched.

8. The method of claim 6, wherein the receiving substrate returns to an original shape after being at least one of thermally activated or magnetically activated.

9. A method, the method comprising:
transferring a plurality of components from a donor substrate to a receiving substrate while it is stretched; and
reducing the stretching force on the receiving substrate in at least one direction so that the components are in a smaller surface area where all components are separated by a new predetermined spacing.

10. A system, the system comprising:
a receiving substrate, the receiving substrate having an elasticity;
a plurality of components being affixed to the receiving substrate, the plurality of components being a distance apart defined by a distance of the plurality of components when formed; and
a substrate stretcher that stretches the receiving substrate such that a location of the set of components is adjusted by a force applied to the receiving substrate via the substrate stretcher stretching the receiving substrate in at least one direction.

11. The system of claim 9, wherein the stretching includes at least one of: elastic or plastic deformation.

12. The system of claim 9, wherein the receiving substrate further includes a set of pillars, and the components are on the pillars.

13. The system of claim 9, wherein the receiving substrate comprises at least one of: elastic materials, viscoelastic materials, elastomers, and shape memory materials including polymers with or without additives.

14. The system of claim 9, wherein the receiving substrate is elastically stretched in at least two directions.

15. The system of claim 9, wherein the receiving substrate returns to an original shape after stretching.

16. The system of claim 9, wherein the receiving substrate maintains a stretched shape after being elastically stretched.

17. The system of claim 15, wherein the receiving substrate returns to an original shape after being at least one of thermally activated or magnetically activated.
